(19) United States
(12) Patent Application Publication
(10) Pub. No.: US 2002/0159491 A1
(43) Pub. Date: Oct. 31, 2002

(54) Surface emitting laser

(76) Inventors: Wenbin Jiang, Thousand Oaks, CA (US); Chan-Long Shieh, Paradise Valley, AZ (US); Xiqing Sun, Gilbert, AZ (US); Hsing-Chung Lee, Calabasas, CA (US)

Correspondence Address: Robert A. Parsons, PARSONS & GOLTRY, Suite 260, 340 East Palm Lane, Phoenix, AZ, 85004, US

(21) Appl. No.: 09/842,507

(22) Filed: Apr. 26, 2001

(51) Int. Cl. H01S 5/00

(52) U.S. Cl. 372/45

(57) ABSTRACT

A surface emitting diode, such as a laser, including an active region positioned between first and second semiconductor layers and extending longitudinally. The active region and at least portions of the first and second semiconductor layers defining first and second facets positioned at opposite ends of the length with the first facet defining a light output for the active region. The active region is adjusted to emit a single mode of light. A reflective element is positioned adjacent to the first facet and at an angle with the first facet for receiving light output from the active region and directing the light perpendicular to the active region.

### FIELD OF THE INVENTION

This invention relates to lasers and more particularly to lasers that generate relatively long wavelengths.

### BACKGROUND OF THE INVENTION

Vertical cavity surface emitting lasers (VCSELs) include first and second mirror stacks formed on opposite sides of an active area. The active area generally includes one or more quantum wells capable of generating light as electrical carriers are supplied. Each mirror stack includes a plurality of pairs of mirrors designed to reflect a portion of light generated in the active area back into the active area for regeneration. The pairs of mirrors in the mirror stacks are formed of a material system generally consisting of two materials having different indices of refraction to provide the reflectivity.

VCSELs have a number of advantages over edge emitting and other types of lasers. One advantage is that a VCSEL emits a circular beam of light which is easier to use or direct through normal optics. Further, VCSELs have a low operating threshold and can be tested on-wafer to reduce costs expended on failed packaged units. However, manufacturing VCSELs that operate in a range including, for example, 1300 nm and 1550 nm is very difficult because of poor monolithic reflectivity at these wavelengths.

In conventional VCSELs, which operate in the 760 nm to 1050 nm range, conventional material systems such as AlGaAs perform adequately. However, for VCSELs outside of this range, other material systems, whose overall performance is poorer, must be used. For example, longer-wavelength light can be generated by using a VCSEL having an InP-based active region. When an InP-based active region is used, however, the epitaxial DBRs lattice matched to the supporting substrate and the active region do not provide enough reflectivity for the VCSELs to operate because of the insignificant difference in the refractive indices between the two DBR constituents. Dielectric mirror stacks can be used instead, but they suffer from poor thermal conductivity. Since the performance of these long-wavelength materials is very sensitive to temperature, the thermal conductivity of the mirror stacks is very important.

Accordingly it is highly desirable to provide a surface emitting long wavelength laser which is easy and inexpensive to manufacture.

It is an object of the present invention to provide new and novel surface emitting long wavelength lasers.

It is another object of the present invention to provide surface emitting long wavelength lasers with short cavities to produce single longitudinal mode operation.

It is another object of the present invention to provide surface emitting long wavelength lasers that are easy to manufacture.

It is another object of the present invention to provide surface emitting long wavelength lasers that do not require expensive and complicated epitaxially grown mirrors.

It is still another object of the present invention to provide surface emitting long wavelength lasers that are tailored to enhance a desired or single longitudinal mode of operation.

It is a further object of the present invention to provide surface emitting long wavelength lasers with surface emission designed to emit a circular beam.

### SUMMARY OF THE INVENTION

To achieve the objects and advantages specified above and others, a single mode surface emitting laser is disclosed which includes an active region positioned between first and second semiconductor layers so as to extend longitudinally parallel to the surface of a substrate. The active region and at least portions of the first and second semiconductor layers define first and second facets positioned at opposite ends of the length with the first facet defining a light output for the active region. The active region is adjusted to emit a single mode of light. A reflective element is positioned adjacent to the first facet and at an angle with the first facet for receiving light output from the active region and directing the light at an angle to the active region.

In a preferred embodiment, the active region is adjusted to produce a single mode of light by forming the active region with a predetermined length. For example, a single mode surface emitting laser is constructed with an active region length such that the wavelength difference between adjacent modes of operation is sufficient to provide single mode operation. The wavelength difference, Δλ, is defined by the equation

Δλ=(λ²/2nL) Δm,

wherein L is the length of the active region cavity, n is the effective index of refraction of the active region cavity, λ is the operating wavelength of the active region cavity, and Δm is the difference between the different order of modes of operation. When Δm=1, Δλ represents the wavelength difference between the adjacent modes.

### BRIEF DESCRIPTION OF THE DRAWINGS

Referring to the drawings:

FIG. 1 is a simplified sectional view of a short cavity surface emitting laser in accordance with the present invention;

FIGS. 2, 3, and 4 are simplified sectional views of other embodiments of short cavity surface emitting lasers with modified reflecting surfaces, in accordance with the present invention;

FIGS. 5, 6, 7, and 8 are sectional views illustrating sequential steps in a method of fabricating a short cavity surface emitting laser in accordance with the present invention;

FIG. 9 is a simplified sectional view of another embodiment of a short cavity surface emitting laser in accordance with the present invention;

FIG. 10 is a graphical representation of the band pass of a portion of a filter used in the short cavity surface emitting laser of FIG. 9; and

FIG. 11 is a simplified sectional view of another embodiment of a short cavity surface emitting laser in accordance with the present invention.

### DESCRIPTION OF THE PREFERRED EMBODIMENT

Turning now to FIG. 1, a simplified sectional view is illustrated of a single mode surface emitting laser 10 in accordance with the present invention. Here it should be understood that, while the preferred embodiment of the present invention is a laser (sometimes referred to as a laser diode), the structure is basically a diode and light emitting diodes, other than lasing diodes, are intended to be included in the disclosure. Laser 10 includes a substrate 12 depicted by a broken line. An area 14 can include a buffer layer for lattice matching the substrate to the subsequent structure. A first cladding layer 15 is epitaxially grown on area 14, an active area 16 is grown on first cladding 15, and a second cladding layer 17 is grown on active area 16. In this embodiment, cladding layers 15 and 17 and active area 16 are referred to generally as an active region. However, it will be understood that many different configurations can be used to produce an active region including quantum wells, quantum dots, etc. and a variety of layers may be used to provide the waveguiding function of cladding layers 15 and 17. Also, while a single layer 16 is illustrated for the active area, it will be understood that the active area can consist of multiple layers. A cap layer 18 is grown on 17 to complete and protect the structure.

Two facets 20 and 21 are formed on either end of the active region to define a length L. Facets 20 and 21 and cladding layers 15 and 17 cooperate to produce a lasing action within active region 16 such that a beam of light is emitted through facet 21. The beam of light emitted through facet 21 generally has an elliptical cross section.

Laser 10 usually operates at many different modes if the mode spacing is small and many cavity modes can be supported by the gain profile of the active region 16, but the length L of active area 16 can be adjusted to allow single mode operation. A single mode surface emitting laser can be constructed by reducing the cavity length such that the wavelength difference between adjacent modes of operation is large enough, compared to the width of the gain profile, such that only one cavity mode is supported by the gain of the active region 16. In this way, a laser with a single longitudinal mode of operation, is produced. Here it should be understood that the term “single longitudinal mode operation” describes the fact that the wavelength spacing of the adjacent modes is increased sufficiently so that amplification occurs only for one selected single mode. In this specific embodiment, the mode selection (i.e. adjacent mode spacing Δλ) is accomplished by adjusting the length L of the active region according to the equation

Δλ=(λ²/2nL) Δm,

where L is the length of the active region cavity, n is the index of refraction of the active region cavity, λ is the operating wavelength of the active region cavity at a given mode, and Δm is the difference between the different order of modes of operation. For the adjacent modes, Δm=1. Therefore, reducing the length L of active area 16 increases the mode wavelength spacing, Δλ, between adjacent modes. Generally, the length L of active area 16 can be reduced to less than 50 μm to provide a laser to operate in a single longitudinal mode, at a wavelength of around 1300 nm or 1550 nm.

As a specific example, if Δm=1, λ=1300 nm, n=3.5, and L=50 μm, using the above equation Δλ=4.8 nm. By reducing the length L to 25 μm, the mode wavelength spacing (Δλ) increases to 9.6 nm. The width of the gain profile of the active region 16 can be around 10-20 nm. Therefore, a carefully designed laser with the right cavity length will have only one cavity mode located near the center of the gain profile, while the adjacent mode will be at the edge or outside of the gain profile. Only the cavity mode near the center of the gain profile will be amplified and lase.

A reflective element 25, which in this embodiment is illustrated as a flat mirror surface, is positioned adjacent to first facet 21 and at an angle with first facet 21. In this embodiment, element 25 is formed as an integral part of the structure by etching, selective deposition, or photolithography method, etc. Also, element 25 is oriented at a 45 degree angle such that light emitted by active area 16 is directed normal to the length of the active region. Also, it will be understood that because a flat mirror is used, the reflected beam will have an elliptical cross section (assuming the laser generates a beam with an elliptical cross-section).

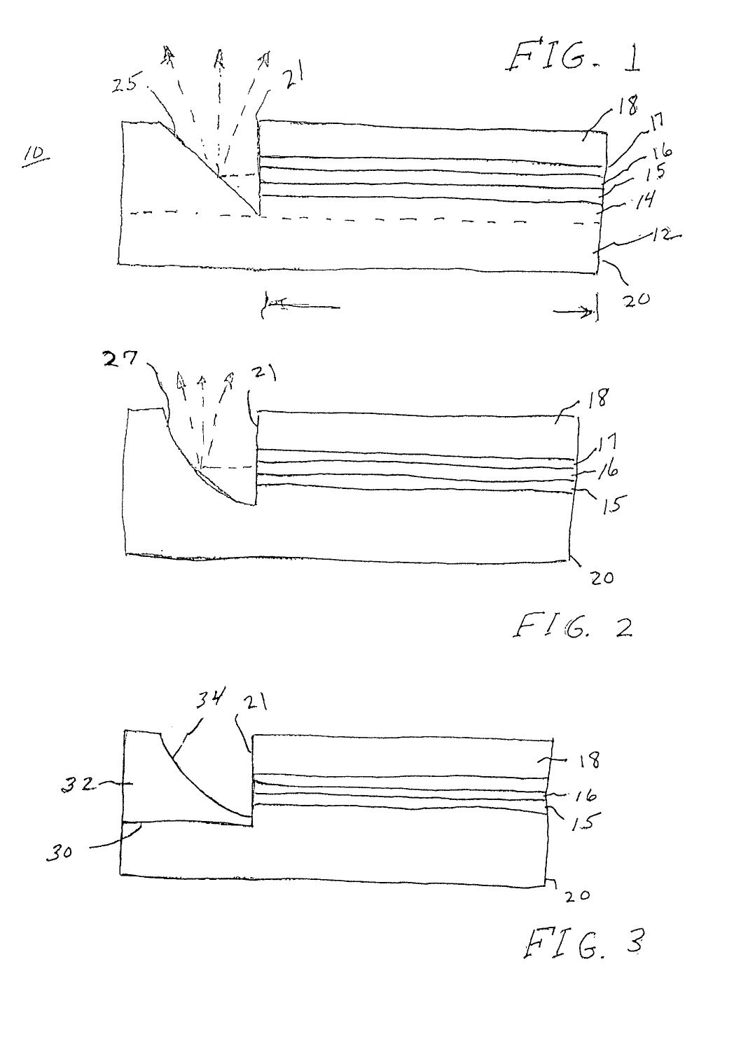

Referring additionally to FIG. 2, a single mode surface emitting laser similar to that described in FIG. 1 is illustrated. However, in this embodiment, a reflective element 27 having a curved surface is included. The surface of reflected element 27 is curved such that the elliptical beam emitted from active area 16 is converted to a beam of a circular cross section. The curve of reflective element 27 is easily obtained and may, for example, be similar to the curve in a standard converging lens.

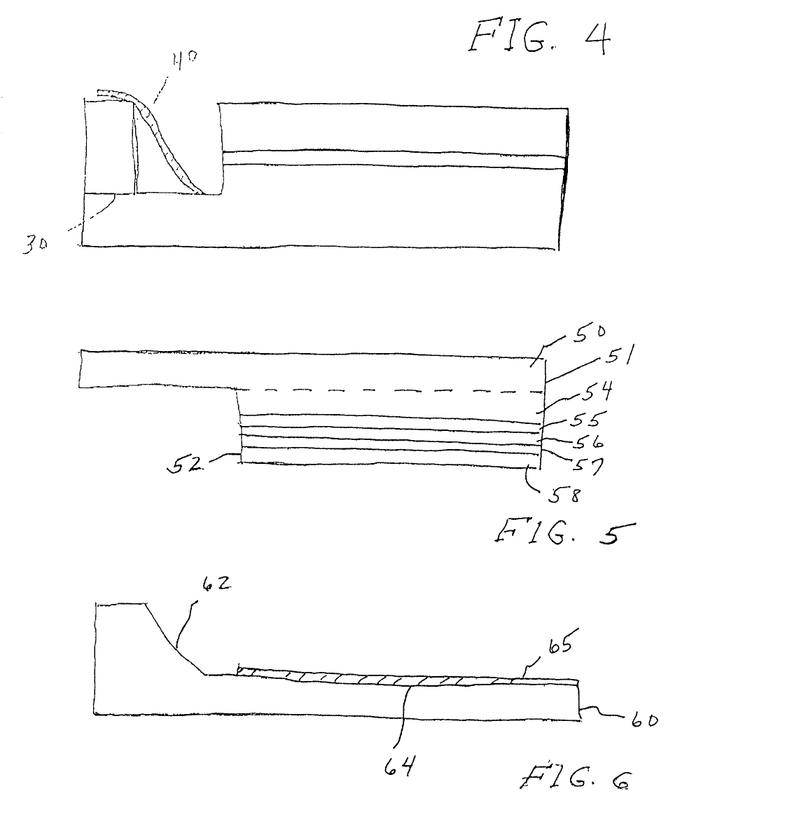

Referring additionally to FIG. 3, another embodiment of a single mode surface emitting laser similar to that described in FIG. 1 is illustrated. Opposed facets 20 and 21 are formed in the epitaxially grown layers, generally as described above. In a preferred embodiment, a microcleaving process is used to form facets 20 and 21, but other forms of cleaving and/or etching and polishing can be used if desired. In this embodiment, the area for the reflecting element is cleaved or etched to provide a flat surface 30. Flat surface 30 is designed to receive an easily etchable or formable material 32. For example, a polymer material (e.g. photoresist SU-8) may be used and exposed at a 45 angle to define the reflective surface. The photoresist can then be cured and a reflective material can be deposited thereon. A reflective surface 34 is then formed in material 32 by any convenient method including developing, etching, chemical mechanical polishing, etc. In some instances is may be convenient to deposit a thin reflective layer (e.g. such as metal) on surface 34 to enhance the reflective qualities. In a further example, illustrated in FIG. 4, a reflective element 40 is formed on flat or curved surface 34 using E-beam evaporation technology.

Referring to FIGS. 5 through 8, a specific example of one method of fabricating a single mode surface emitting laser is illustrated. Referring specifically to FIG. 5, a first substrate 50 is depicted by a broken line. An area 54 can include a buffer layer for lattice matching the substrate to the subsequent structure. A first cladding layer 55 is epitaxially grown on area 54, an active area 56 is grown on first cladding 55, and a second cladding layer 57 is grown on active area 56. In this embodiment, cladding layers 55 and 57 and active area 56 are referred to generally as an active region. However, it will be understood that many different configurations can be used to produce an active region including quantum wells, quantum dots, etc. and a variety of layers may be used to provide the waveguiding function of cladding layers 55 and 57. Also, while a single layer 56 is illustrated for the active area, it will be understood that the active area can consist of multiple layers. A cap layer 58 is grown on 57 to complete and protect the structure. Opposed facets 51 and 52 can be formed by cleaving, microcleaving, etching, etc.

Referring additionally to FIG. 6, a second substrate 60 is illustrated. Substrate 60 is etched or otherwise formed to define a reflective surface 62 and a flat mounting surface 64. In a preferred embodiment, reflective surface 62 is curved so as to convert an elliptical beam to a circular beam as described above. It will be understood that reflective surface 62 can be flat or any desired shape to provide the desired beam shape and direction. It should also be understood that the reflective surface 62 can be formed separately on a different structure and positioned on flat mounting surface 64. For example, reflective surface 62 can be formed with photoresist, exposed at a 45 angle, developed, cured, and coated with a reflective material. A layer of electrically conductive material 65 is deposited on mounting surface 64 and, as will be described below, is used as an external electrical contact for the laser.

Referring additionally to FIG. 7, the surface of cap layer 58 in the structure of FIG. 5 is bonded to the surface of the contact material 65 so that light emitted from active area 56 is directed onto reflective surface 62. In addition, a portion of contact material 65 remains exposed to provide an external electrical contact to the capped layer of the laser 58. Substrate 50 is then removed, as illustrated in FIG. 8, by etching, chemical mechanical polishing, etc., to allow the light beam redirected by surface 62 to be emitted at an angle relative to active region 56. A second contact metal 66 is deposited on the surface of the laser exposed by removal of substrate 50. It should be understood that reflective element 62 can be formed directly on substrate 50 of FIG. 5 to form the structure in FIG. 8. Wafer bonding and substrate removal process is not necessary.

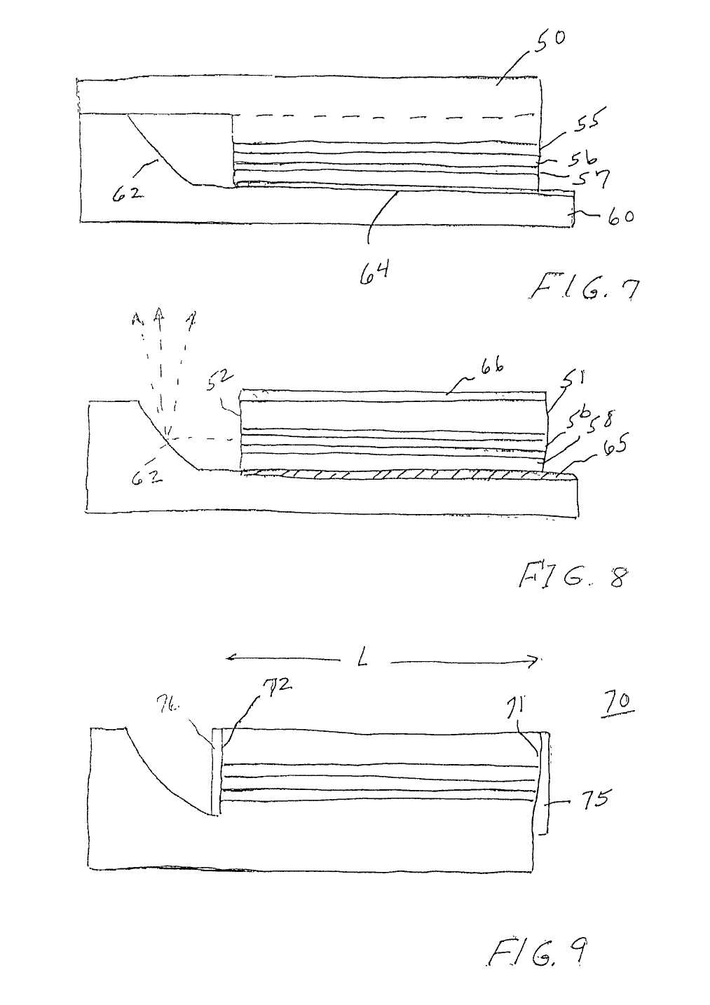

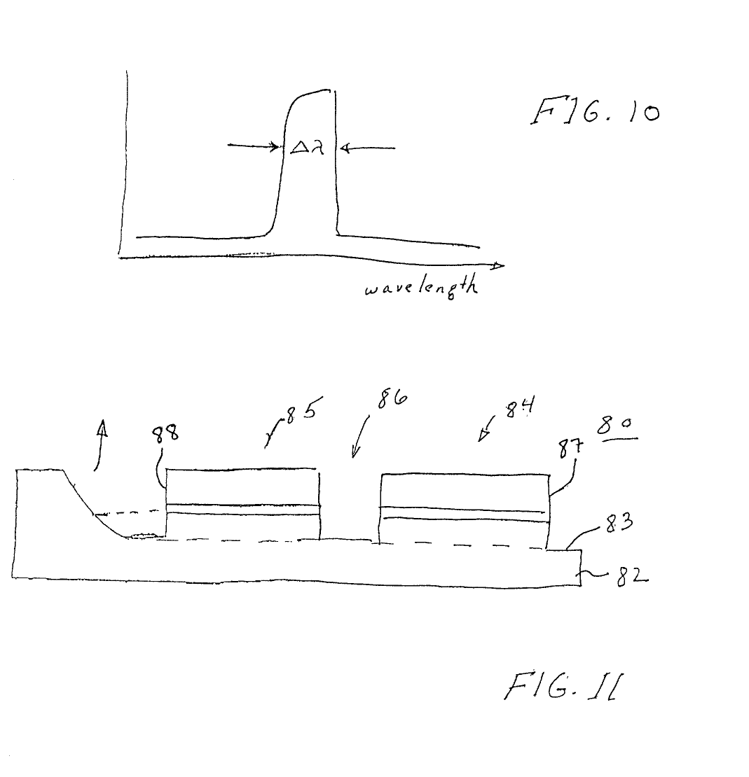

Referring now to FIG. 9, a single mode surface emitting laser 70 is illustrated, generally as described above. Laser 70 has opposed facets 71 and 72 defining the length L. To reduce the laser threshold current, facets 71 and 72 are coated with dielectric materials 75 and 76, respectively, which increase the reflectivity of facets 71 and 72. As the length L is reduced, the gain of laser 70 is reduced, but by adding the coating more light is reflected and amplified because the facet losses decrease. At least one of the coatings 75 or 76 can be narrow band, as illustrated in FIG. 10. The coating bandwidth Δλ_{coating} is best designed to be smaller than the mode wavelength spacing Δλ, which substantially eliminates adjacent modes. While in the embodiment illustrated in FIG. 9, coating 76 could be narrow band, either or both of the coatings 75 and 76 could be narrow band in other embodiments.

Referring now to FIG. 11, a coupled cavity single mode surface emitting laser 80 is illustrated. Laser 80 includes a substrate 82 having a mounting surface 83 on which is positioned a first cavity 84 and a second cavity 85. First cavity 84 and second cavity 85 are each similar to the active region described in conjunction with FIG. 1. Also, cavities 84 and 85 are spaced apart to provide a gap 86 there between. By correctly spacing cavities 84 and 85, gap 86 forms a Fabry-Perot resonator with only one wavelength transparent due to resonance. This gap provide a filter effect equivalent to FIG. 10. Thus, only one longitudinal mode of operation will be supported that is resonant to this coupled cavity. Here it will be understood that laser 80 can be fabricated in an embodiment similar to laser 10 of FIG. 1 by forming the active area with two facets 87 and 88 and forming gap 86 between the facets.

In a different embodiment, an array of coupled cavity lasers (e.g. each similar to laser 80) can be made on one wafer. One coupled cavity laser is resonant to λ₁ and emits light at the wavelength λ₁ by setting the gap 86 to one appropriate spacing, while the adjacent coupled cavity laser is resonant to λ₂ and emits light at λ₂ by setting the gap 86 to a different spacing. Thus, an array of lasers with different gap spacings can be provided to obtain lasers of varying wavelength for multi-signal operation, such as wave division multiplexing.

Thus, single mode surface emitting lasers have been disclosed which generate longer-wavelength light and which are easy to manufacture because there are only a few layers to grow (no DBR stacks). An In-based active region can be used to emit long wavelength light because high reflectivity stacks of mirrors are not required. Also, because high reflectivity stacks are not required, electrical contacts and heatsinking are relatively easy to make. Thus, a novel surface emitting long wavelength laser with short cavities to produce single longitudinal mode operation is disclosed. Also, the present surface emitting long wavelength laser is easy to manufacture. Several of the lasers can be combined into an array to provide multi-signal operation, such as WDM.

While we have shown and described specific embodiments of the present invention, further modifications and improvements will occur to those skilled in the art. We desire it to be understood, therefore, that this invention is not limited to the particular forms shown and we intend in the appended claims to cover all modifications that do not depart from the spirit and scope of this invention.

1. A surface emitting laser comprising:
an active region positioned between first and second semiconductor layers and extending a length along a longitudinal axis, the active region and at least portions of the first and second semiconductor layers defining first and second facets positioned at opposite ends of the length with the first facet defining a light output for the active region, the active region being adjusted to emit a single mode of light; and
a reflective element positioned adjacent the first facet and at an angle with the first facet for receiving light output from the active region and directing the light at an angle to the direction of the length.

2. A surface emitting laser as claimed in claim 1 wherein the length of the active region is less than approximately 50 μm.

3. A surface emitting laser as claimed in claim 2 wherein the active region is constructed with a length such that a wavelength difference between adjacent modes of operation is sufficient to provide single mode operation.

4. A surface emitting laser as claimed in claim 1 wherein the active region includes compound materials lattice matched to indium-phosphide (InP).

5. A surface emitting laser as claimed in claim 1 wherein the active region includes an active area sandwiched between cladding layers, the cladding layers being constructed to act as waveguides such that light generated in the active region is guided within the active area and the opposing facets, and the active area and cladding layers are epitaxial layers of semiconductor material grown on a semiconductor substrate.

6. A surface emitting laser as claimed in claim 1 wherein the reflective element and the active region are formed on a common substrate.

7. A surface emitting laser as claimed in claim 6 wherein the reflective element directs the light normal to the direction of the length of the active region.

8. A surface emitting laser as claimed in claim 7 wherein the active region emits a beam with an elliptical cross section and the reflective element is curved such that the beam is converted to a beam with a circular cross section.

9. A surface emitting laser as claimed in claim 1 further including a filter positioned on the first facet for filtering out modes such that the laser emits only one longitudinal mode.

10. A surface emitting laser as claimed in claim 9 wherein the filter ha s a bandwidth smaller than a spacing between the one longitudinal mode and adjacent modes.

11. A surface emitting laser as claimed in claim 1 wherein a gap with a specific length is etched between the first facet and the second facet to form a coupled cavity laser so that the laser operates at a wavelength controlled by the gap length.

12. A surface emitting laser comprising:
an active region positioned between first and second semiconductor layers and extending a length along a longitudinal axis, the active region and at least portions of the first and second semiconductor layers defining first and second facets positioned at opposite ends of the length with the first facet defining a light output for the active region, the length of the active region being adjusted to emit a single mode of light by adjusting the wavelength difference, Δλ, defined by the equation
Δλ=(λ²/2nL) Δm,
wherein L is the length of the active region cavity, n is the index of refraction of the active region cavity, λ is the operating wavelength of the active region cavity at a given mode, and Δm is the difference between the different modes of operation; and
a reflective element positioned adjacent the first facet and at an angle with the first facet for receiving light output from the active region and directing the light at an angle to the direction of the length.

13. A surface emitting laser as claimed in claim 12 wherein the reflective element and the active region are formed on a common substrate.

14. A surface emitting laser as claimed in claim 13 wherein the reflective element directs the light normal to the direction of the length of the active region.

15. A surface emitting laser as claimed in claim 14 wherein the active region emits a beam with an elliptical cross section and the reflective element is curved such that the beam is converted to a beam with a circular cross section.

16. A method of fabricating a surface emitting laser comprising the steps of:
forming an active region on a first substrate between first and second semiconductor layers and extending a length along a longitudinal axis, the active region and at least portions of the first and second semiconductor layers being formed to define first and second facets positioned at opposite ends of the length with the first facet defining a light output for the active region, adjusting the active region to emit a single mode of light;
forming a reflective surface on a second substrate;
mounting the active region on the second substrate with the reflective surface adjacent the first facet and at an angle with the first facet for receiving light output from the active region and directing the light at an angle to the direction of the length; and
removing the first substrate to expose the reflective surface.

17. A method as claimed in claim 16 wherein the step of forming an active region includes the steps of epitaxially growing the active region on the semiconductor substrate and growing a bonding layer on the active region.

18. A method as claimed in claim 17 wherein mounting the active region includes bonding the bonding layer to the surface of the second substrate.

19. A method as claimed in claim 18 further including forming an electrical contact layer on the second substrate and bonding the bonding layer to the electrical contact layer.

20. A method as claimed in claim 16 wherein the step of forming the active region and the first and second semiconductor layers to define first and second facets positioned at opposite ends of the length includes microcleaving.

21. A surface light emitting diode comprising:
an active region positioned between first and second semiconductor layers and extending a length along a longitudinal axis, the active region and at least portions of the first and second semiconductor layers defining first and second facets positioned at opposite ends of the length with the first facet defining a light output for the active region; and
a polymer reflective element positioned adjacent the first facet and at an angle with the first facet for receiving light output from the active region and directing the light at an angle to the direction of the length.

22. A surface light emitting diode as claimed in claim 21 wherein the polymer reflective element includes cured photoresist material.

23. A surface light emitting diode as claimed in claim 21 wherein the polymer reflective element directs the light toward perpendicular to the surface of the epitaxial layers.

24. A surface light emitting diode as claimed in claim 23 wherein the polymer reflective element is curved to circularize the light beam.

25. A surface light emitting diode as claimed in claim 21 wherein the diode is a laser diode.

26. A surface light emitting diode as claimed in claim 21 wherein the first facet and the second facet are etched facets.

27. A surface light emitting diode as claimed in claim 21 wherein the first facet and the second facet are cleaved facets.

28. A surface light emitting diode as claimed in claim 27 wherein at least one of the first facet and the second facet is a micro-cleaved facet.
